(19) United States
(12) Patent Application Publication
(10) Pub. No.: US 2021/0074950 A1
(43) Pub. Date: Mar. 11, 2021

(54) PACKAGE STRUCTURE

(71) Applicant: STARDUST OPTRONICS CORPORATION, Hsinchu City (TW)

(72) Inventors: MENG-HUNG HSIN, NEW TAIPEI CITY (TW); YI-HAO SU, TAINAN CITY (TW)

(21) Appl. No.: 16/812,006

(22) Filed: Mar. 6, 2020

(30) Foreign Application Priority Data
Sep. 11, 2019 (CN) 201910858917.8

(51) Int. Cl. H01L 51/52; H01L 27/32

(52) U.S. Cl. CPC H01L 51/5253; H01L 51/5281; H01L 27/3246

(57) ABSTRACT

The present invention provides a package structure. The package structure includes a substrate, an electronic component layer disposed on the substrate, and an organic polymer layer disposed on the electronic component layer, wherein the organic polymer layer has a fluorine content greater than 55 percent by weight and less than or equal to 85 percent by weight. The present invention further provides another package structure. The package structure includes a substrate, an electronic component layer disposed on the substrate, an organic polymer layer disposed on the electronic component layer, an optical function layer disposed on the organic polymer layer, and an adhesive layer disposed between the organic polymer layer and the optical function layer and configured to adhere the optical function layer to the organic polymer layer.

### BACKGROUND

The present invention is related to a package structure, and in particular, to a package structure using an organic polymer layer having favorable water-resistance properties.

With the advancement and progression of related technologies, electronic products have become indispensable to modern life. During the manufacturing process of the electronic products, a packaging process is typically carried out to form a package structure that protects the electronic components within the electronic products, so as to, for example, protect the electronic components from moisture, oxygen or physical damage. in order to obtain a package structure with a satisfactory protection capability, increased reliability, and reduced manufacturing cost, extensive effort has been devoted to improvements in the manufacturing process, material and structure of the package structure.

### BRIEF SUMMARY OF THE INVENTION

The present invention provides a package structure, which includes an organic polymer layer in direct contact with an electronic component layer, thereby reducing the manufacturing cost and complexity of the package structure and increasing manufacturing productivity.

Embodiments of the present invention provide a package structure including a substrate, an electronic component layer, and an organic polymer layer. The electronic component layer is disposed on the substrate, the organic polymer layer is disposed on the electronic component layer, and the organic polymer layer has a fluorine content greater than 55 percent by weight and less than or equal to 85 percent by weight.

Embodiments of the present invention further provide a package structure including a substrate, an electronic component layer disposed on the substrate, an organic polymer layer disposed on the electronic component layer, an optical function layer disposed on the organic polymer layer, and an adhesive layer disposed between the organic polymer layer and the optical function layer and configured to adhere the optical function layer to the organic polymer layer.

The organic polymer layer in the package structure of the present invention is in direct contact with the electronic component layer, with no corresponding detrimental chemical reaction occurring between the two, and the organic polymer layer protects the electronic component layer from moisture and oxygen, eliminating the need for another protective layer. As a result, compared to conventional package structures, the present invention eliminates the need for fabrication of at least one passivation layer having an inorganic material between the electronic component layer and the organic polymer layer, and at the same time simplifies the fabrication process and the layers of the package structure, thereby reducing the cost and increasing the productivity, as well as reducing the thickness of the package structure.

### BRIEF DESCRIPTION OF THE DRAWINGS

FIG. 1 is a schematic sectional view of the package structure according to an embodiment of the present invention.

FIG. 2 is a partial schematic top view of the package structure according to an embodiment of the present invention.

FIG. 3 is a partial schematic sectional view of the package structure according to an embodiment of the present invention.

FIG. 4 is a schematic sectional view of the package structure according to a second embodiment of the present invention.

FIG. 5 is a schematic sectional view of the package structure according to the second embodiment of the present invention.

### DETAILED DESCRIPTION

Embodiments of the present invention are provided below, and the contents of the present invention and the effects to be achieved are described in connection with the accompanying drawings so that persons having ordinary skill in the art may further understand the present invention. It should be noted that the accompanying drawings are simplified schematic drawings, and accordingly, only components and structural relationships relevant to the present invention are shown so as to provide a clear description to the basic framework or embodiments of the present invention, whereas the actual components and layouts may be more complex. Further, to facilitate the description, the components shown in the accompanying drawings of the present invention are not drawn to reflect their actual numbers, shapes, or sizes, and the specific ratio of said components may be adjusted depending on the design needs.

Throughout the present disclosure, the terms “comprising,” “including” and/or “having,” when used in connection with the existence of said features, areas, steps, operations, and/or components, do not exclude the existence or addition of one or more other features, areas, steps, operations or components. When a component such as a layer or an area is referred to as being disposed “on” another component (or a variant thereof) or extended “onto” another component, it may be disposed on or extended onto said another component directly, or there may be an intervening component between the two. On the other hand, when a component is referred to as being disposed “directly” on another component (or a variant thereof) or extended “directly” onto another component, there is no intervening component between the two. Also, when a component is referred to as being “electrically connected” to another component (or a variant thereof), it may be connected to another component directly or connected to another component indirectly via one or more components.

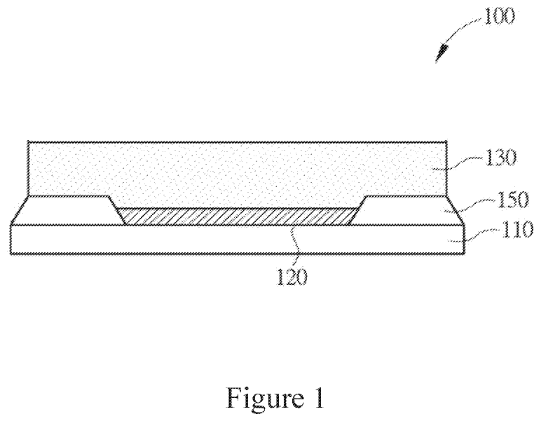

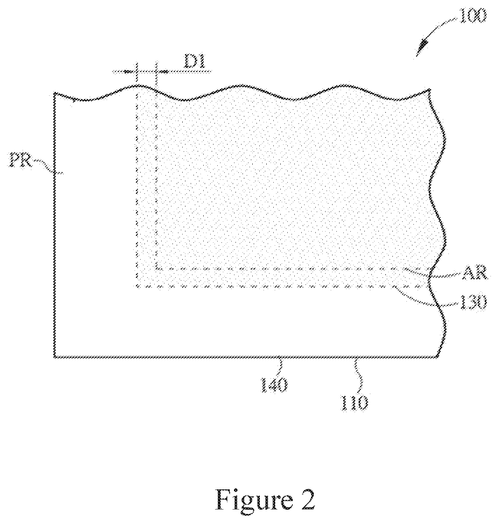

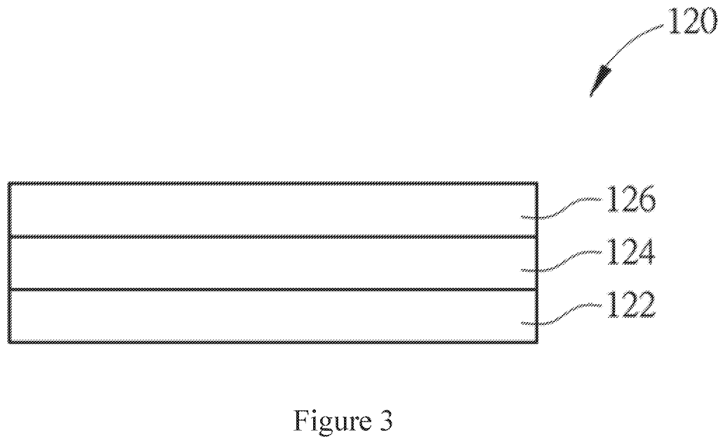

Please refer to FIG. 1 to FIG. 3; FIG. 1 is a schematic sectional view of the package structure according to the first embodiment of the present invention; FIG. 2 is a partial schematic top view of the package structure according to the first embodiment of the present invention; and FIG. 3 is a schematic sectional view of the electronic component layer according to one embodiment of the present invention; wherein the position shown in FIG. 2 is a corner of the package structure 100 of the first embodiment. The present package structure 100 may be a package structure of an organic light-emitting diode (OLED) display; however, the present invention is not limited thereto, and the package structure 100 may be a package structure of another type of display, a package structure of an electronic component such as a capacitor, or a package structure including other suitable electronic components such as a microelectromechanical system (MEMS). As shown in FIG. 1 and FIG. 2, the package structure 100 according to the present embodiment comprises a substrate 110, an electronic component layer 120, an organic polymer layer 130 and a protective layer 140, and has an active area. AR and a peripheral area PR disposed at the periphery of the active area AR, wherein the active area AR is configured to display the image, and the peripheral area PR. is configured to accommodate a portion of the circuits.

The substrate 110 is configured to bear electronic components, structures or films, and the substrate 110 of the present embodiment may be a hard substrate, such as a glass substrate, plastic substrate, quartz substrate or sapphire substrate; or a flexible substrate comprising materials such as polyimide (PT) materials or polyethylene terephthalate (PET) materials; however, the present invention is not limited thereto. In some embodiments, the substrate 110 has a minimum bend radius not greater than 10 mm. The minimum bend radius is measured to the inside curvature, and is the minimum radius one can bend the substrate 110 without kinking it, damaging it, or shortening its life. In some embodiments, several conductive traces may be disposed in the substrate 110 and form circuitry to provide current to the electronic component layer 120.

The electronic component layer 120 is disposed on the substrate 110, and comprises at least one electronic component for providing specific functions, wherein the electronic component may be at least one of an active device and a passive device, and since the package structure 100 of the present embodiment is the package structure of the OLED display, the electronic component layer 120 in the active area AR may comprise the organic light-emitting diode structure and other necessary electronic components (e.g., conductive wires), so as to provide the light-emitting and image-displaying functions; however, the present invention is not limited thereto. In another embodiment, when the package structure 100 is a capacitor package structure, then the electronic component layer 120 may comprise a capacitor.

In some embodiments, the electronic component layer 120 is an organic light-emitting layer. In some embodiments, the electronic component layer 120 includes a plurality of light-emitting pixels. The electronic component layer 120 may include light-emitting units arranged in an array. Each independent light-emitting unit is separated from other adjacent light-emitting units. In some embodiments, the light-emitting units are configured to be in recesses of the substrate 110.

As shown in FIG. 3, the electronic component layer 120 of the present embodiment may have two conductive electrodes 122, 126 disposed therewithin and an active layer 124 disposed between the two conductive electrodes 122, 126. For example, the active layer 124 may convert the electricity into solar energy by means of charge combination or charge separation; however, the membrane of the electronic component layer 120 is not limited thereto. Alternatively, the electronic component layer 120 may further comprise an insulation layer configured to separate the conductive wires wherein the insulation layer includes a silicon oxide or silicon nitride layer. Moreover, the package structure 100 of the present embodiment may further comprise, a pixel -defining layer 150 (PDL), which is configured to define the active area AR and separate individual pixels; that is, separate the electronic component layer 120 within the active area AR; however, the present invention is not limited thereto.

Referring hack to FIGS. 1 and 2, the organic polymer layer 130 is directly disposed on the electronic component layer 120; that is, the organic polymer layer 130 is in direct contact with the electronic component layer 120, so as to protect the electronic component layer 120. The organic polymer layer 130 has a barrier function and may improve weather resistance. The organic polymer layer 130 may include a material that blocks moisture and oxygen to prevent infiltration of moisture and oxygen that could damage electronic components in the electronic component layer 120. That is, the organic polymer layer 130 does not need to be provided with other inorganic or organic protective layers having barrier functions.

In the present embodiment, the organic polymer layer 130 is fabricated by firstly coating or printing oligomers directly on the electronic component layer 120, followed by irradiating the oligomers with an energy source so that the oligomers are polymerized to form the organic polymer layer 130, wherein the energy source may be heat energy or radiation energy. In such a configuration, the oligomers may be polymerized with heating or light irradiation; for example, heated to about 60° C. to about 120° C. for polymerization. In another embodiment, the oligomers may be irradiated with the light having a wavelength of about 300 nanometers (nm) to about 500 nm for polymerization, and the power applied to the oligomers may be about 0.1 to 100 mW/cm². However, the fabrication of the organic polymer layer 130 is not limited thereto.

In the conventional package structure, when the conventional film containing organic materials is in contact with the electronic component layer, after the energy irradiation of the manufacturing process, the energy initiator in the organic material-containing film releases free radicals or similar ionized molecules that undergo a chemical reaction with the materials in the electronic component layer, thereby jeopardizing the functionality or operation of the electronic component layer and affecting the protection efficacy of the conventional organic materials. To mitigate such issues, after the completion of the fabrication of the electronic component layer, a passivation layer (e.g., a silicon oxide layer or a silicon nitride layer) having inorganic materials is generally formed on the electronic component layer, and then an organic material-containing film is formed on the passivation layer so as to protect the electronic component layer; that is, an inorganic passivation layer is required between the conventional organic film and the electronic component layer so as to separate the electronic component layer from the organic material. Since the organic polymer layer 130 of the present embodiment may be in direct contact with the electronic component layer 120, the organic polymer layer 130 is designed so as to not be susceptible to the chemical reaction and deterioration upon contact with the electronic component layer 120. In some embodiments, by making the fluorine content ratio of the electronic component layer 120 significantly different from the fluorine content ratio of the organic polymer layer 130, the organic polymer layer 130 does not chemically react upon contact with the electronic component layer 120, and thus the organic polymer layer 130 does not damage the electronic component layer 120.

In some embodiments, the organic polymer layer has a fluorine content greater than 55 percent by weight and less than or equal to 85 percent by weight. The aforementioned weight percentages are ratios of the molecular weight of fluorine to the molecular weight of the polymer. In some embodiments, the electronic component layer 120 has a fluorine content of less than 5 percent by weight.

Since fluorine has a high polarity, the organic polymer layer 130 having the fluorine content may have a hydrophobic surface, that is, a water-repellent property, and may block the contact of the moisture with the electronic component layer 120 and improve the water-blocking property.

In some embodiments, the fluorine content of the organic polymer layer 130 is between 60 percent by weight and 75 percent by weight. in some embodiments, the fluorine content of the organic polymer layer 130 is between 65 percent by weight and 70 percent by weight.

In some embodiments, the organic polymer layer 130 has a molecular weight between 15,000 and 300,000. In this range of molecular weight, the organic polymer layer 130 has a dense property, which may block oxygen from coming into contact with the electronic component layer 120. In some embodiments, the molecular weight of the organic polymer layer 130 is between 20,000 and 200,000.

The organic polymer layer 130 comprises a material polymerizable to form at least two polymers of the polymethyl methacrylate (PMMA)-based polymers, such as acrylate or derivatives thereof, methyl acrylate or derivatives thereof, or methyl methacrylate or derivatives thereof; however, the present invention is not limited thereto.

As illustrated in FIG. 2, the size of the organic polymer layer 130, as seen in a top view, may be greater than the size of the active area AR; that is, the organic polymer layer 130 at least covers the active area AR of the electronic component layer 120, so as to provide better protection to the electronic component layer 120. In addition, in the present embodiment, the periphery of the organic polymer layer 130 may extend outside of the active area AR by a distance D1 of no less than 1 micrometer (μm); however, the present invention is not limited thereto.

In the conventional package structure, one or more protective layers are provided on the film layer containing organic materials to ensure that the upper surface of the package structure is dense enough to prolong and improve the protection effect. The protective layer is, for example, an inorganic insulating layer. Examples of the material of the inorganic insulating layer include silicon oxide, silicon oxynitride, silicon nitride and at least one other suitable material providing protection, such as water resistance, to the OLED. Each protective layer may be fabricated using deposition processes such as plasma-enhanced chemical vapor deposition (PECVD) or atomic layer deposition (ALD).

However, since the organic polymer layer 130 of the present embodiment includes materials having high water resistance and high oxygen barrier, there is no need for an additional inorganic protective layer over the organic polymer layer 130, and the simplified fabrication process thus reduces cost, increases productivity, and reduces the thickness of the package structure 100.

The thickness of the organic polymer layer 130 of the present embodiment may be between 0.1 micrometer and about 10 micrometers, so as to encapsulate the particles that may adhere to the electronic component layer 120 and cause discharging during the fabrication process. Additionally, the package structure 100 of the present embodiment may further comprise other optional films or layers depending on the need; for example, the package structure 100 may further comprise a color filter (CF) layer or a black matrix (BM) layer, disposed on the organic polymer layer 130, to improve the display quality. The package structure of the present invention is not limited to the above-mentioned embodiments, however, and additional embodiments are described below. To simplify the discussion, in the following descriptions, the same or similar components are designated with the same or similar numeral numbers and repetitive descriptions of similar portions are omitted for the sake of brevity.

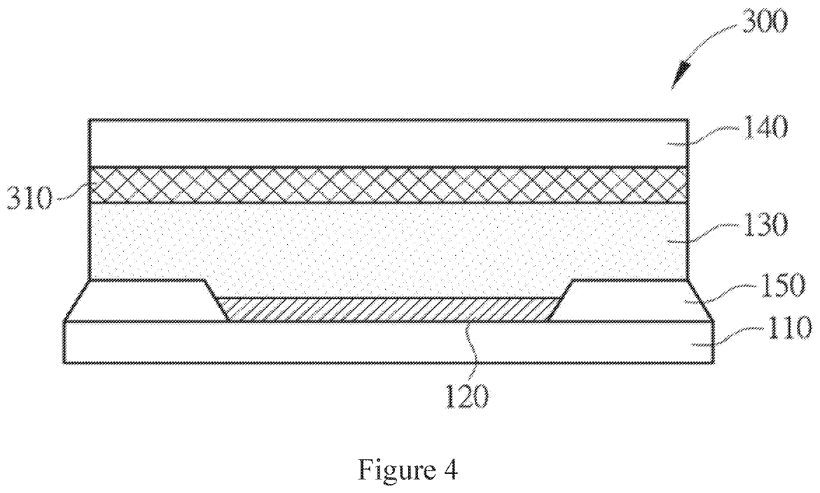

Please refer to FIG. 4, which is a schematic sectional view of the package structure according to a second embodiment of the present invention. As shown in FIG. 4, the difference between the present embodiment and the first embodiment is that the package structure 200 of the present embodiment may further include an optical function layer 410 disposed on the organic polymer layer 130, and an adhesive layer 310 disposed between the organic polymer layer 130 and the optical function layer 410. The adhesive layer 310 of the present embodiment is adhesive on both sides. The adhesive layer 310 may be in direct contact with the organic polymer layer 130 and in direct contact with the optical function layer 410 to adhere the organic polymer layer 130 and the optical function layer 410. By using the adhesive layer 310, the optical function layer 410 may be adhered more securely on the surface of the package structure 200. In addition, the adhesive layer 310 may also have sealing and water- and oxygen-insulating functions.

The optical function layer 410 is configured to improve the imaging quality and effect. In the present embodiment, the optical function layer 410 may be adhered to the adhesive layer 310 and provides optical functions. For example, the optical function layer 410 may be a polarizing plate or an anti-reflection film; however, the present invention is not limited thereto.

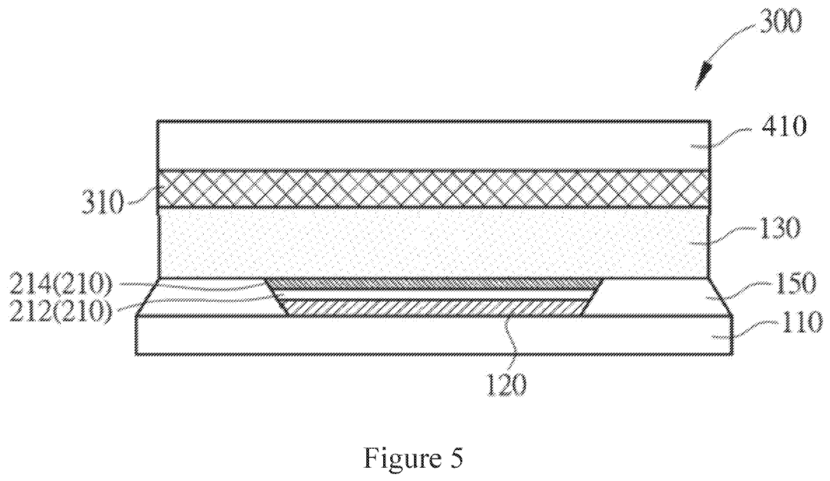

Please refer to FIG. 5. FIG. 5 is a schematic sectional view of the package structure according to a third embodiment of the present invention. As shown in FIG. 5, the difference between the present embodiment and the first embodiment is that at least one inorganic insulating layer 210 of the package structure 300 of the present embodiment is disposed between the organic polymer layer 130 and the electronic component layer 120; that is, the organic polymer layer 130 of the present embodiment may be disposed not directly on the electronic component layer 120, such that the organic polymer layer 130 and the electronic component layer 120 are not in direct contact.

The material of the inorganic insulating layer 210 may comprise, for example, silicon oxide, silicon oxynitride, silicon nitride and at least one other material suitable for use in the inorganic insulating materials of the OLED, so as to improve the protection capability, such as water resistance. In FIG. 5, two illustrative inorganic insulating layers 210 (one first inorganic insulating layer 212 and one second inorganic insulating layer 214) are shown. The two inorganic insulating layers 212 and 214 are shown disposed between two pixel-defining layers 150, but the number and arrangement of the inorganic insulating layers 210 are not limited to those shown in the illustration.

In view of the foregoing, since the organic polymer layer of the package structure according to the present invention has a fluorine content greater than 55 percent by weight and less than or equal to 85 percent by weight, may be in direct contact with the electronic component layer, and does not undergo a chemical reaction with the electronic component layer that could otherwise compromise the organic polymer layer or the electronic component layer, it is feasible to maintain the protection efficacy of the organic polymer layer. In addition, the organic polymer layer provides effective blocking of moisture and oxygen, and no additional protective layer is required. Hence, compared with the conventional package structure, the present invention eliminates the need for a protective layer on the organic polymer layer, and at the same time simplifies the fabrication process and the layers of the package structure, thereby reducing cost, increasing productivity, and reducing the thickness of the package structure.

The foregoing outlines features of preferred embodiments of the present invention; however, the present invention is not limited thereto. As can be appreciated by persons having ordinary skill in the art, various changes and modifications may be made to the present invention. Any modifications, equivalent substitutions, improvements and the like are encompassed in the scope of the present invention.

What is claimed is:

1. A package structure, comprising:
a substrate;
an electronic component layer, disposed on the substrate; and
an organic polymer layer disposed on the electronic component layer, wherein the organic polymer layer has a fluorine content greater than 55 percent by weight and less than or equal to 85 percent by weight.

2. The package structure of claim 1, wherein the fluorine content of the organic polymer layer is greater than 60 percent by weight and less than or equal to 75 percent by weight.

3. The package structure of claim 2, wherein the fluorine content of the organic polymer layer is greater than 65 percent by weight and less than or equal to 70 percent by weight.

4. The package structure of claim 1, wherein the organic polymer layer has a molecular weight between 15,000 and 300,000.

5. The package structure of claim 4, wherein the molecular weight of the organic polymer layer is between 20,000 and 200,000.

6. The package structure of claim 1, wherein the organic polymer layer comprises a polymer of at least two compounds polymerizable to form a methyl methacrylate-based polymer.

7. The package structure of claim 1, wherein the organic polymer layer comprises acrylate or derivatives thereof, methyl acrylate or derivatives thereof or methyl methacrylate or derivatives thereof.

8. The package structure of claim 1, wherein the organic polymer layer is formed by polymerizing oligomers with energy irradiation.

9. The package structure of claim 1, wherein the electronic component layer has a fluorine content of less than 5 percent by weight.

10. The package structure of claim 1, wherein the organic polymer layer comprises a hydrophilic surface.

11. The package structure of claim 1, wherein the electronic component layer comprises an organic light-emitting diode structure.

12. A package structure, comprising:
a substrate;
an electronic component layer, disposed on the substrate;
an organic polymer layer, disposed on the electronic component layer,
an optical function layer, disposed on the organic polymer layer, and
an adhesive layer, disposed between the organic polymer layer and the optical function layer, configured to adhere the optical function layer to the organic polymer layer.

13. The package structure of claim 12, wherein the adhesive layer is in direct contact with the organic polymer layer and in direct contact with the optical function layer.

14. The package structure of claim 12, wherein the optical function layer includes at least one of a filter film, a polarizing plate or an anti-reflection film.

15. The package structure of claim 12, wherein the organic polymer layer is configured to protect the electronic component layer from moisture and oxygen.

16. The package structure of claim 12, wherein the organic polymer layer is in direct contact with the electronic component layer.

17. The package structure of claim 12, wherein the organic polymer layer comprises a hydrophilic surface.

18. The package structure of claim 12, wherein the organic polymer layer has a fluorine content greater than 55 percent by weight and less than or equal to 85 percent by weight.

19. The package structure of claim 18, wherein the fluorine content of the organic polymer layer is greater than 65 percent by weight and less than or equal to 70 percent by weight.

20. The package structure of claim 12, wherein the organic polymer layer has a molecular weight between 20,000 and 200,000.
